(19) United States
(12) Patent Application Publication
(10) Pub. No.: US 2026/0026027 A1
(43) Pub. Date: Jan. 22, 2026

(54) HIGH ELECTRON MOBILITY TRANSISTOR AND METHOD

(71) Applicant: Infineon Technologies Austria AG, Villach (AT)

(72) Inventors: Hyeongnam KIM, Chandler, AZ (US); Mohamed IMAM, Tempe, AZ (US); Ziyang XIAO, Phoenix, AZ (US)

(21) Appl. No.: 18/778,777

(22) Filed: Jul. 19, 2024

(51) Int. Cl. H01L 29/778; H01L 29/20; H01L 29/66

(52) U.S. Cl. CPC H10D 30/475; H10D 30/015; H10D 62/8503

(57) ABSTRACT

A HEMT structure comprising an epitaxial stack comprising a channel layer composed of a first type III-V semiconductor, and a barrier layer epitaxially grown on the channel layer and composed of a second type III-V semiconductor. The first type III-V semiconductor and the second type III-V semiconductor are such that a heterojunction between the channel layer and the barrier layer forms a two-dimensional electron gas (2DEG) within the channel layer. A gate node is positioned over the barrier layer, and a source node positioned on a lateral side of the gate node so as to be in conductive contact with the 2DEG at least when the 2DEG is continuous under the gate node. A floating p-doped region is positioned over the barrier layer and is on a second lateral side of the gate node opposite the source node, the floating p-doped region comprising a third type III-V semiconductor material.

### BACKGROUND

Electronic circuits typically include transistors, which function as electronic switches that regulate or control current flow in portions of the circuit. One type of transistor is a field-effect transistor in which a voltage is applied to a gate terminal to turn the transistor on and off. A semiconductor channel region is disposed between the drain terminal and the source terminal. When the transistor is on, current flows through the semiconductor channel region between the source terminal and the drain terminal. When the transistor is off, lesser or no current flows through the semiconductor channel region between the source terminal and the drain terminal. The gate terminal is disposed over the semiconductor channel region between the source terminal and the drain terminal. Voltage on the gate terminal generates a field that affects whether the semiconductor channel region conducts current—hence the term “field-effect transistor”.

One type of field-effect transistor is a “high electron mobility transistor” (often called an “HEMT”). High electron mobility transistors are used to control much higher voltages and currents. Higher voltage differences between the gate terminal and the drain terminal cause a large electric field peak to be produced around the semiconductor channel region on the side of the gate terminal more proximate to the drain terminal. To help reduce the magnitude of the electric field peak, high electron mobility transistors often also include one or more grounded field plates disposed above the semiconductor channel region between the gate terminal and the drain terminal. The field plates help to reduce electric field peaks that would have existed on the drain side of the gate terminal, as each field plate helps to step down the large voltage difference between the drain terminal and gate terminal.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Embodiments described herein relate to a high-electron mobility transistor (HEMT) structure comprising an epitaxial stack that includes a channel layer composed of a first type III-V (read “type three five”) semiconductor, and a barrier layer epitaxially grown on the channel layer and composed of a second type III-V semiconductor. The first type III-V semiconductor and the second type III-V semiconductor are such that a heterojunction between the channel layer and the barrier layer forms a two-dimensional electron gas (2DEG) within the channel layer. The structure further includes a gate node positioned over the barrier layer, and a source node positioned on a first lateral side of the gate node so as to be in conductive contact with the 2DEG at least when the 2DEG is continuous under the gate node. Furthermore, a floating p-doped region is positioned over the barrier layer and is on a second lateral side of the gate node—the second lateral side being laterally opposite the first lateral side. The floating p-doped region is composed of a third type III-V semiconductor material. Embodiments described herein also relate to a method for fabricating such an HEMT structure.

The floating p-doped region operates to reduce the electric field peak occurring at the semiconductor channel region on the second lateral side of the gate terminal. The p-doped region will have lower 2DEG density thereunder, which allows the structure to have less channel-to-substrate voltages than if the p-doped region was not present. An advantage of this is that the epitaxial layer may be thicker, thus allowing the device to have less vertical leakage, and potentially even to handle higher voltages. Thus, embodiments described herein promote the efficient use of electrical power, and the mitigation of electrical waste. This can thereby reduce the need for power generation, thereby having positive impacts on the environment.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is a simplified diagram of a High Electron Mobility Transistor (HEMT) used to describe the general principle of operation of a HEMT;

FIG. 2 illustrates a HEMT structure that includes a floating p-doped region, in accordance with the principles described herein;

FIG. 3 illustrates a HEMT transistor that includes an instance of the HEMT structure of FIG. 2 as well as a drain node;

FIG. 4 illustrates a HEMT structure in the form of a bi-directional switch that includes two laterally mirrored instances of the HEMT structure of FIG. 2;

FIG. 5 illustrates a HEMT structure in the form of a bi-directional switch that is similar to FIG. 4, except that there is a central floating p-doped region, instead of two lateral floating p-doped regions;

FIGS. 6A through 6D each illustrate top views of various example bi-directional switches in which the shape of the p-doped regions in the plane of the epitaxial stack are mirrored about a mid-point between the gate nodes of the respective bi-directional switch;

FIG. 7 illustrates a flowchart of a method for fabricating a HEMT structure in accordance with the principles described herein;

FIGS. 8A through 8C illustrate various stages of fabrication of the HEMT structure of FIG. 2 when fabricated using the method of FIG. 7;

FIGS. 9A through 9I illustrate subsequent fabrication of the HEMT structure of FIG. 2 in accordance with the First Embodiment; and

FIGS. 10A through 10I illustrate subsequent fabrication of the HEMT structure of FIG. 2 in accordance with the Second Embodiment.

### DETAILED DESCRIPTION

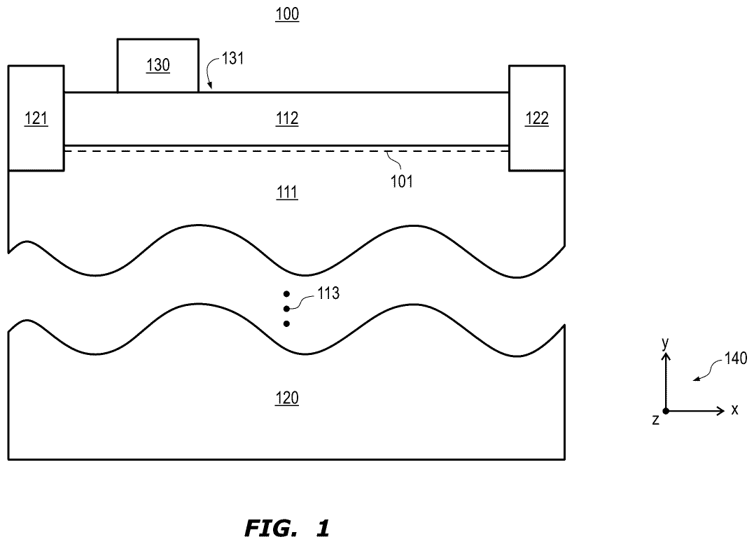

Embodiments described herein relate to a type of transistor called a “field-effect transistor”, and more particularly to a type of field-effect transistor called a “high electron mobility transistor” or (HEMT) that is effective at switching large currents and voltages. Specifically, the principles described herein relate to a particular HEMT structure that permits effective electric field management despite the switching of high voltages, thus reducing electrical waste, and promoting positive environmental impact. The HEMT structure does this using one or more floating p-doped regions. Accordingly, first, the general principles of operation of a field-effect transistor will be described. Thereafter, the general structure and principles of operation of HEMTs will be described with respect to FIG. 1. Next, embodiments of HEMT structures that use one of more floating p-doped regions to mitigate electric fields in accordance with the principles described herein will be described with respect to FIG. 2 and subsequent figures.

Field-effect transistors function as electronic switches that can be turned on or off by applying a voltage to a gate node. A semiconductor channel region is disposed between a source node and a drain node. The gate node is disposed over the semiconductor channel region between the source node and the drain node. When the field-effect transistor is on, current flows through the semiconductor channel region between the source node and the drain node. When the field-effect transistor is off, lesser or no current flows through the semiconductor channel region between the source node and the drain node. Voltage applied to the gate node generates a field that affects whether the semiconductor channel region conducts current—hence the term “field-effect transistor”. In an “enhancement mode” field-effect transistor, the transistor is on when a sufficiently positive gate-to source voltage (above a threshold voltage) is applied to the gate node, and off when the gate-to-source voltage is zero. In contrast, in a “depletion mode” field-effect transistor, the transistor is on when the gate-to-source voltage is zero, and off when the gate-to-source voltage is sufficiently negative.

One type of field-effect transistor is a “high electron mobility transistor” (often called a “HEMT”). The term “high electron mobility transistor” is a term that is known in the art. Hereafter, as in the art, a “high electron mobility transistor” will also be referred to as a HEMT. HEMTs are used to control much higher voltages and currents. FIG. 1 is a simplified diagram of a HEMT transistor structure 100 merely used to describe the general principle of operation of a HEMT transistor. As the diagram is simplified, dimensions and proportions are not drawn to scale, but nevertheless the diagram is suitable to describe the general principles of a HEMT.

For clarity, a coordinate system 140 is also shown in FIG. 1. The y-axis is the vertical axis with the positive y direction being upwards, and the negative y direction being downwards. The x-axis is the horizontal axis, with the rightward direction being the positive x direction, and the leftward direction being the negative x direction. Finally, the z-axis is an axis that extends perpendicular to the xy plane, and extends towards and away from the reader, with the positive z-direction extending towards the reader.

The HEMT transistor structure 100 may be formed by epitaxially growing an epitaxial stack on a substrate. The epitaxial growth direction will be referred to while now describing spatial nomenclature that will be used herein, understanding it does not matter what orientation the HEMT transistor structure 100 has with respect to the direction of gravity. The terms horizontal and vertical are thus used merely to describe relative spatial positioning of elements in FIG. 1 with respect to the direction of epitaxial growth. The same spatial nomenclature is used throughout the other figures as well.

In this description and in the claims, a direction of growth of this epitaxial stack will sometimes be referred to as a “vertical” direction (which is along the vertical axis—the y-axis in FIG. 1). Consequently, terms describing relative vertical position (such as “beneath”, “below”, and “above” and so forth) are with respect to this vertical direction. For instance, if a second layer is epitaxially grown on a first layer, the second layer will be “above” the first layer, and the first layer will be “beneath” the second layer.

Furthermore, in this description and in the claims, the horizontal direction (which may also be referred to as a “lateral” direction) is the direction perpendicular to the direction of growth of the epitaxial stack. Furthermore, a horizontal plane is a plane that is perpendicular to the epitaxial growth direction. For instance, each layer in the epitaxial stack is along a respective horizontal plane. As an example, a left side might be one “lateral side”, whereas a right side may be referred to as the other “lateral side”.

Returning to FIG. 1, the HEMT transistor structure 100 includes a semiconductor substrate 120 that forms a foundation on which further layers may be epitaxially grown to formulate part of a transistor structure. The semiconductor substrate 120 may be any semiconductor, including silicon. Layers epitaxially grown on top of the semiconductor substrate 120 will be referred to hereinafter as an “epitaxial stack”.

The epitaxial stack includes a channel semiconductor layer 111 epitaxially grown using the semiconductor substrate 120 as a foundation. The channel semiconductor layer 111 may be comprised of any suitable semiconductor, including Gallium Nitride (GaN). The ellipsis 113 represents that there may be any number of layers in the epitaxial stack between the semiconductor substrate 120 and the channel semiconductor layer 111. As an example only, strain relief layers may be formed between the semiconductor substrate 120 and the channel semiconductor layer 111 to thereby improve the mechanical stability and electrical performance of the HEMT transistor structure 100. Nevertheless, the principles described herein are not limited to what (if any) layers are between the semiconductor substrate 120 and the channel semiconductor layer 111. Suffice it to say that the semiconductor substrate 120 is rigidly coupled to the channel semiconductor layer 111 to provide adequate support for the channel semiconductor layer 111 as well as the remainder of the epitaxial stack, in the sense that all epitaxial layers are coupled to a substrate on which they are grown.

A barrier semiconductor layer 112 is epitaxially grown on the channel semiconductor layer 111 such that the barrier semiconductor layer 112 is immediately above the channel semiconductor layer 111. A heterojunction interface is present between the channel semiconductor layer 111 and the barrier semiconductor layer 112. The barrier semiconductor layer 112 may be comprised of any suitable semiconductor such as Aluminum Gallium Nitride (AlGaN). The differences in the bandgap profiles of the channel semiconductor layer 111 (e.g., GaN) and the barrier semiconductor layer 112 (e.g., AlGaN) are such that the conduction band edge of the channel semiconductor layer is pulled downwards near the heterojunction interface, thus creating an energy potential well that dips below the Fermi level vertically just within the channel semiconductor layer 111. Because the well is below the Fermi level, free electrons exist in this well, forming a highly conductive two-dimensional electron gas (“2DEG”) 101 (represented by a horizontal dashed line in FIG. 1).

The vertical thickness of the region in which such free electrons exist corresponds to the short vertical span of the well that dips below the Fermi level. Thus, the 2DEG 101 is vertically thin. However, the region in which such free electrons exist is a horizontal plane. Thus, this region is called a “Two-Dimensional” Electron Gas to emphasize its planar form. The 2DEG is not literally a gas, but gas is a highly mobile state of matter, and thus the term “gas” is used to emphasize the mobility of the electrons in the 2DEG. The reference to “Electron Gas” in the term is thus to emphasize that the electrons in the 2DEG have high mobility. The 2DEG is also referred to as a “sea of electrons” also emphasizing the mobility of the electrons in the 2DEG. The 2DEG may form the channel region of a power semiconductor to allow passage of high currents with relatively low resistance. Thus, 2DEGs are indispensable in high-frequency and high-power electronics.

A source node 121 is in conductive contact with the 2DEG 101, which means that electrons may flow freely between the source node 121 and the 2DEG 101 (see leftmost portion of the 2DEG 101 as shown in FIG. 1). This may be because the source node 121 and the 2DEG 101 are in direct contact (as shown in FIG. 1), or perhaps they are not in direct contact, but close enough that the electrons may still flow between the source node 121 and the 2DEG 101. Likewise, the drain node 122 is also in conductive contact with the 2DEG 101 (see rightmost portion of the 2DEG 101 as shown in FIG. 1). If the 2DEG 101 is continuous between the source node 121 and the drain node 122, the 2DEG 101 serves as a channel through which electrons may flow between the source node 121 and the drain node 122.

A gate node 130 is proximate the 2DEG 101 such that voltages applied to the gate node 130 (or more specifically the electrical fields caused by those voltages) control whether the 2DEG 101 is continuous between the source node 121 and the drain node 122. When the gate node 130 is off, the 2DEG 101 is discontinuous underneath the gate node 130. On the other hand, when the gate node 130 is on, then the 2DEG 101 is continuous underneath the gate node 130. If the HEMT transistor structure 100 is an enhancement mode transistor, the HEMT transistor structure 100 is off when a zero gate-to-source voltage is applied to the gate node 130, and on when a sufficiently positive gate-to-source voltage is applied to the gate node 130. If the HEMT transistor structure 100 is a depletion mode transistor, the HEMT transistor structure 100 is on when a zero gate-to-source voltage is applied to the gate node 130, and off when a sufficient negative gate-to-source voltage is applied to the gate node 130. Thus, by controlling the continuity of the 2DEG 101 between the source node 121 and the drain node 122, voltages applied to the gate node 130 control whether the transistor represented by the HEMT transistor structure 100 is on or off.

HEMTs are used to control much higher voltages and currents. For example, high voltages may be applied to the drain node 122 that may be even hundreds of volts, or perhaps even above a thousand volts. The gate node 130 is typically positioned closer to the source node 121 than the drain node 122 to provide some protection against such high voltages, such as to allow the use of field plates (not shown in FIG. 1) that are laterally between the gate node 130 and the drain node 122.

When a HEMT is turned off (i.e., when zero gate-to-source voltage is applied to the gate node), high voltage differences between the gate node and the drain node cause a large electric field to be produced in the semiconductor channel region particularly in the part (see arrow 131) of the semiconductor channel region that is closest to the side of the gate node 130 that is more proximate to the drain node 122. HEMTs often also include one or more grounded field plates (not shown in FIG. 1) disposed above the semiconductor channel region between the gate node 130 and the drain node 122. A field plate is, for example, a layer of deposited conductive material, such as metal. These field plates reduce the magnitude of the electric field occurring in the drain-side of the gate node (e.g., at arrow 131), and reduce the maximum electric field in the overall semiconductor channel region. This allows the HEMT to operate at higher voltages and/or have reduced dimensions.

Hereinafter, a brief introduction of a HEMT structure in accordance with the principles described herein will next be provided, followed by a more detailed description of embodiments of the HEMT structure with respect to FIG. 2 and subsequent figures.

Embodiments described herein relate to a high electron mobility transistor (HEMT) structure comprising an epitaxial stack that includes a channel layer composed of a first type III-V (read “type three five”) semiconductor, and a barrier layer epitaxially grown on the channel layer and composed of a second type III-V semiconductor. The first type III-V semiconductor and the second type III-V semiconductor are such that a heterojunction between the channel layer and the barrier layer forms a 2DEG within the channel layer. The structure further includes a gate node positioned over the barrier layer, and a source node positioned on a first lateral side of the gate node so as to be in conductive contact with the 2DEG at least when the 2DEG is continuous under the gate node. Furthermore, a floating p-doped region is positioned over the barrier layer and is on a second lateral side of the gate node—the second lateral side being laterally opposite the first lateral side. The floating p-doped region is composed of a third type III-V semiconductor material.

In accordance with the principles described herein, the floating p-doped region operates to reduce the electric field peak occurring at the semiconductor channel region on the second lateral side of the gate terminal. When the 2DEG is discontinuous under the gate node (i.e., when the transistor is off), the p-doped region will have lower 2DEG density thereunder, which allows the structure to have less channel-to-substrate voltages than if the p-doped region was not present. An advantage of this is that the epitaxial layer may be thicker, thus allowing the device to have less vertical leakage, and potentially even to handle higher voltages. The floating p-doped region may operate to further reduce the maximum electric field present in the semiconductor channel region than would be possible with the field plates alone. That said, the principles described herein are not limited to the use of the p-doped region in HEMTs that have field plates. Thus, embodiments described herein promote the efficient use of electrical power, and the mitigation of electrical waste. This can thereby reduce the need for power generation, thereby having positive impacts on the environment.

FIG. 2 illustrates a HEMT structure 200 that represents just one embodiment of a limited variety of embodiments enabled by this description. Again, the coordinate system 140 is illustrated for convenient reference. The HEMT structure 200 includes an epitaxial stack 210 that includes a channel layer 211 composed of a first type III-V semiconductor, and a barrier layer 212 epitaxially grown on the channel layer 211 and composed of a second type III-V semiconductor. The channel layer 211 and the barrier layer 212 may function as described above with respect to the channel semiconductor layer 111 and the barrier semiconductor layer 112 of FIG. 1. Thus, the channel layer 211 and the barrier layer 212 induce a 2DEG 201 just within the channel layer 211.

A “type III-V semiconductor” is a term of art and refers to a compound semiconductor that includes elements for each of group III and group V of the periodic chart of the elements. As an example, Gallium Nitride (GaN) is a type III-V semiconductor because it includes gallium (which is a group III element) and Nitrogen (which is a group V element). Additionally, Aluminum Gallium Nitride (AlGaN) is also a type III-V semiconductor because Aluminum is also a group III element. As a side note, all semiconductors include some level of impurities. But the term “type III-V semiconductor” is still applicable even if there are some other elements that are not group III or group V elements. Type III-V semiconductors often have a wide bandgap and thus can be more suitable for forming a heterojunction sufficient to generate a 2DEG than are lesser bandgap semiconductors.

As an example only, the channel layer 211 may be composed of GaN, and the barrier layer 212 may be composed of AlGaN. However, there are many type III-V semiconductors that may be used to form the channel layer 211 and the barrier layer 212. Nevertheless, the type III-V semiconductor that forms the channel layer 211 (i.e., the “first type III-V semiconductor”) and the type III-V semiconductor that forms the barrier layer 212 (i.e., the “second type III-V semiconductor”) are chosen such that a heterojunction between the channel layer 211 and the barrier layer 212 forms the 2DEG 201 within the channel layer 211.

Such would be the case, for example, if the first type III-V semiconductor was GaN, and the second type III-V semiconductor was AlGaN, at least for some ratios of Aluminum to Gallium in the AlGaN (i.e., at least for some values of x in Al_{X}Ga₍₁₋ₓ₎N). Such would also be the case, for example, if the first type III-V semiconductor was Gallium Arsenide (GaAs), and the second type III-V semiconductor was Aluminum Gallium Arsenide (AlGaAs), again at least for some ratios of Aluminum to Gallium. Such would also be the case if the first type III-V semiconductor was Indium Gallium Nitride (InGaN), and the second type III-V semiconductor was Aluminum Indium Gallium Nitride (AlInGaN). Nevertheless, again, these listed types of III-V semiconductor are just examples of selections that would cause a 2DEG (such as the 2DEG 201) to form just within the channel layer 211.

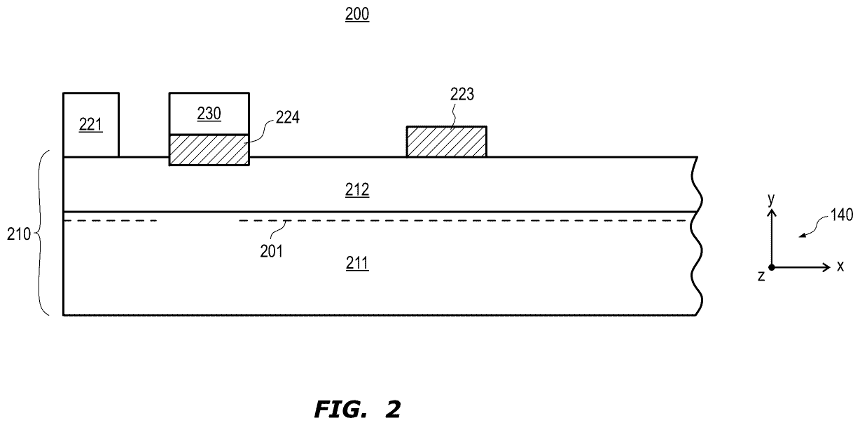

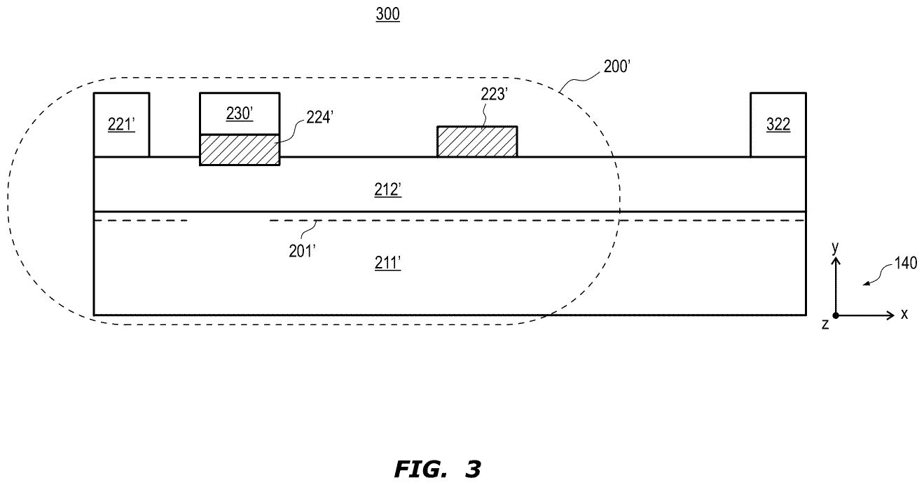

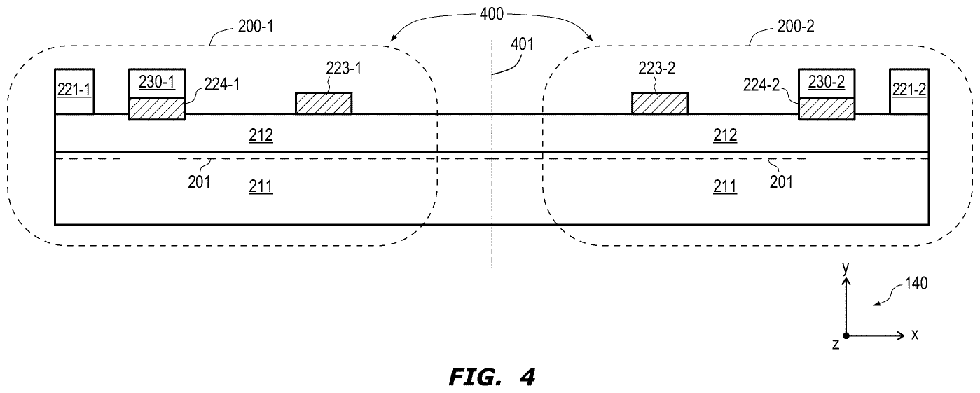

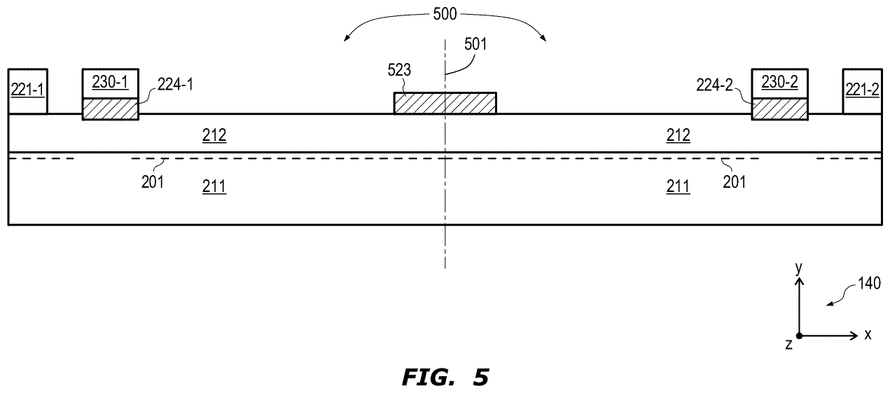

The HEMT structure 200 also includes a gate node 230 positioned over the barrier layer 212. Furthermore, the HEMT structure 200 also includes a source node 221 positioned on a first lateral side (the left side in FIG. 2) of the gate node 230 so as to be in conductive contact with the 2DEG 201 at least when the 2DEG 201 is continuous under the gate node 230. Note that there is no drain node shown in the HEMT structure 200. While in some embodiments the HEMT structure 200 forms a single transistor (as in FIG. 3), in other embodiments the HEMT structure 200 forms part of a bi-directional switch (as in FIGS. 4 and 5) in which two HEMTs are coupled in series with a common drain and no drain node—or at least no drain contact. The HEMT structure 200 may be used in either embodiment, and thus the drain node is omitted from FIG. 2.

In accordance with the principles described herein, a floating p-doped region 223 is positioned over the barrier layer 212 and on a second lateral side (e.g., a right side in FIG. 2) of the gate node 230. This second lateral side is on the opposite lateral side of the gate node 230 as compared to the lateral side of the gate node 230 at which the source node 221 is positioned. In other words, the source node 221 and the floating p-doped region 223 are on opposite lateral sides of the gate node 230. In the example of FIG. 2, the source node 221 is to the left of the gate node 230, and the floating p-doped region 223 is to the right of the gate node 230.

As mentioned, the floating p-doped region 223 is comprised of a third type III-V semiconductor material, the second lateral side being laterally opposite the first lateral side. The floating p-doped region 223 is shown with rightward leaning cross hatching to represent that the p-doped region is p-doped. As an example only, this third type III-V semiconductor might be the same material as the first type III-V semiconductor except for being p-doped. For example, if the channel layer 211 is formed of GaN, the floating p-doped region 223 may be composed also of GaN except for being further p-doped. The floating p-doped region 223 is “floating” in that it is not conductively connected to any voltage source. The voltage of the floating p-doped region 223 simply floats to whatever amount is caused by the electrical fields that surround the floating p-doped region 223.

The floating p-doped region 223 contacts the barrier layer 212. The presence of the floating p-doped region 223 so close to the 2DEG 201 causes the 2DEG 201 to thin underneath the floating p-doped region 223 due to the close presence of the p-type ions therein. This thinning occurs most notably when the HEMT structure 200 is off (i.e., when the 2DEG 201 is discontinuous under the gate node 230). This thinning reduces the electrical field experienced at the drain side of the gate node 230 when the HEMT structure 200 is off. Optionally, the p-type ions within the floating p-doped region 223 may be caused to come even closer to the 2DEG 201 by forming the floating p-doped region 223 within a vertically recessed portion of the barrier layer 212.

Although the principles described herein may also apply to depletion mode HEMT structures, FIG. 2 illustrates an enhancement mode HEMT structure 200. In enhancement mode structures, a p-doped region is positioned vertically between the gate node and the barrier layer. The electric fields induced by the p-type ions in such a p-doped region are what causes the 2DEG underneath the gate node to be depleted (discontinuous) underneath the gate node when the gate-to-source voltage is zero. Thus, the HEMT structure 200 includes a second p-doped region 224 formed vertically between the gate node 230 and the barrier layer 212. In one embodiment, this second p-doped region 224 is formed of the same type III-V semiconductor as the floating p-doped region 223. This is represented by the second p-doped region 224 also being filled with rightward leaning cross hatching. Accordingly, the first floating p-doped region 223 and the second p-doped region 224 may be formed from the same epitaxial layer (of course subject to appropriate patterning). For instance, if the first floating p-doped region 223 was p-doped GaN, the second p-doped region 224 may also be p-doped GaN.

In one embodiment, the HEMT structure 200 forms part of a HEMT transistor. FIG. 3 illustrates a HEMT transistor 300 that includes an instance 200′ of the HEMT structure 200. Specifically, the elements 201′, 211′, 212′, 221′, 223′, 224′ and 230′ of FIG. 3 may be the same as elements 201, 211, 212, 221, 223, 224 and 230, respectively, of FIG. 2. However, the HEMT transistor 300 also includes a drain node 322. The drain node 322 is position on the right side of the floating p-doped region 223′ such that when the 2DEG 201′ is continuous underneath the gate node 230′, the 2DEG 201 is continuous between the drain node 322 of the HEMT transistor 300 and the source node 221′ of the HEMT transistor 300, rendering the HEMT transistor 300 on. Although only one floating p-doped region 223′ is illustrated for the HEMT transistor 300, there may be multiple p-doped regions between the gate node 230 and drain node 322 of the HEMT transistor 300.

On the other hand, the HEMT structure 200 (or rather two instances of the HEMT structure 200) may also form part of a bi-directional switch with common drains. FIG. 4 illustrates a HEMT structure 400 that takes a first instance 200-1 of the HEMT structure 200, and a second instance 200-2 of the HEMT structure 200. The HEMT structure 200-1 of FIG. 4 includes the same elements described above for the HEMT structure 200 of FIG. 2, except with the suffix “-1” added to each element number. The HEMT structure 200-2 of FIG. 4 also includes the same elements described above for the HEMT structure 200 of FIG. 2, except with the suffix “-2” added to each element number, and except that the elements are laterally symmetrically positioned about a lateral mid-point 401 between the first gate node 230-1 of the first instances 200-1 of the HEMT structure 200 and the second gate node 230-2 of the second instance 200-2 of the HEMT structure 200. The channel layer 211, the barrier layer 212 and the 2DEG 201 are each shared between the first HEMT structure 200-1 and the second HEMT structure 200-2, and thus these elements are not shown with a suffix “-1” or “-2”.

The HEMT structure 400 represents a bi-directional switch, with the first gate node 230-1 and the second gate node 230-2 being control nodes for the bi-directional switch and configured to control current flow between the first source node 221-1 and the second source node 221-2 through the bi-directional switch. Note that there is no accessible drain terminal of either HEMT structures 200-1 and 200-2. Instead, the drain of each HEMT structure 200-1 is merely the 2DEG 201 as it is floating at various voltages between the two gate nodes 230-1 and 230-2. Although the HEMT structure 400 only shows one floating p-doped region on each side of the lateral mid-point 401 (p-doped region 223-1 to the left of the lateral mid-point 401, and p-doped region 223-2 to the right of the lateral mid-point 401), there may be multiple floating p-doped regions on each side of the lateral mid-point 401. The HEMT structure 400 has the advantage of the HEMT structure 200 of FIG. 2 in managing electrical fields near the gate nodes, but the HEMT structure 400 further operates as a bi-directional switch.

FIG. 5 illustrates a HEMT structure 500 that is similar to the HEMT structure 400 of FIG. 4, except now there is just a single floating p-doped region 523 that is centered on the lateral mid-point 501 of the HEMT structure 500. Embodiments described herein also include a combination of FIGS. 4 and 5 in which there is a floating p-doped region that is centered on the mid-point of the HEMT structure (as in FIG. 5) as well as one or more other floating p-doped regions that are mirrored on each side of the mid-point of the HEMT structure (as in FIG. 4).

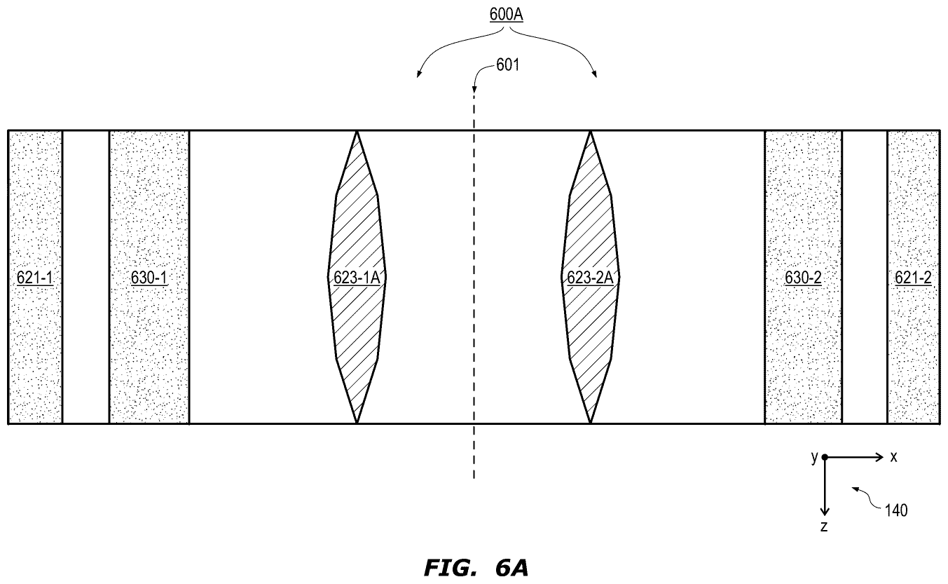

In some implementations, to promote symmetric operation, which is important in bi-directional switches, the patterning of the p-doped layer is such that a shape of the second p-doped layer mirrors the shape of the third doped layer in a plane of epitaxial stack. FIG. 6A illustrates a top view (in the negative y-direction) of a HEMT structure 600A that takes the form of a bi-directional switch. Source nodes 621-1 and 621-2 represent the two bi-directional switch terminals that are in the flow of current. On the other hand, gate nodes 630-1 and 630-2 represent the two control terminals of the bi-directional switch. The HEMT structure 600A further has a mid-point 601 between the two gate nodes 630-1 and 630-2.

As shown, there are two floating p-doped regions 623-1A and 623-2A that have a particular shape in the xz plane that is mirrored about the mid-point 601. The shape of the p-doped regions 623-1A and 623-2A is shown as being a complex diamond shape, but the shape may be of any form, and just a few of an infinite variety of examples will be described with respect to FIGS. 6A through 6D. In some embodiments, the shape is designed such that the maximum electrical field at the gate nodes 630-1 and 630-2 is kept relatively uniform (and at a low level) across the entire gate width (i.e., for all positions along the z-axis).

FIG. 6B through FIG. 6D illustrates additional examples of the HEMT structure 600A of FIG. 6A, except that the shape (in the xz plane) of the p-doped regions 621-1A and 621-2A are different. Thus, the labels for the source nodes 621-1 and 621-2 and the gate nodes 630-1 and 630-2 retain their same element numbers, but the p-doped regions have different labeling. That is, while in FIG. 6A, the p-doped regions are labelled as p-doped regions 623-1A and 623-2A, in FIG. 6B they have the labels 623-1B and 623-2B, in FIG. 6C they have the labels 623-1C and 623-2C, and in FIG. 6D they have the labels 623-1D and 623-2D.

FIG. 6B illustrates an example of a HEMT structure 600B that is similar to the HEMT structure 600A of FIG. 6A, except that the p-doped regions 623-1B and 623-2B are rectangular in the xz plane. FIG. 6C illustrates an example of a HEMT structure 600C that is similar to the HEMT structure 600B of FIG. 6B, except that there are multiple p-doped regions 623-1C that are rectangular in the xz plane and arranged along the z direction, and symmetrically about the mid-point 601 there are multiple p-doped regions 623-2C that are also rectangular in the xz plane and arranged along the z direction. FIG. 6D illustrates an example of a HEMT structure 600D that is similar to the HEMT structure 600B of FIG. 6B, except that there are multiple p-doped regions 623-1D that are rectangular in the xz plane and arranged along the x direction, and symmetrically about the mid-point 601 there are multiple p-doped regions 623-2D that are also rectangular in the xz plane and arranged along the x direction.

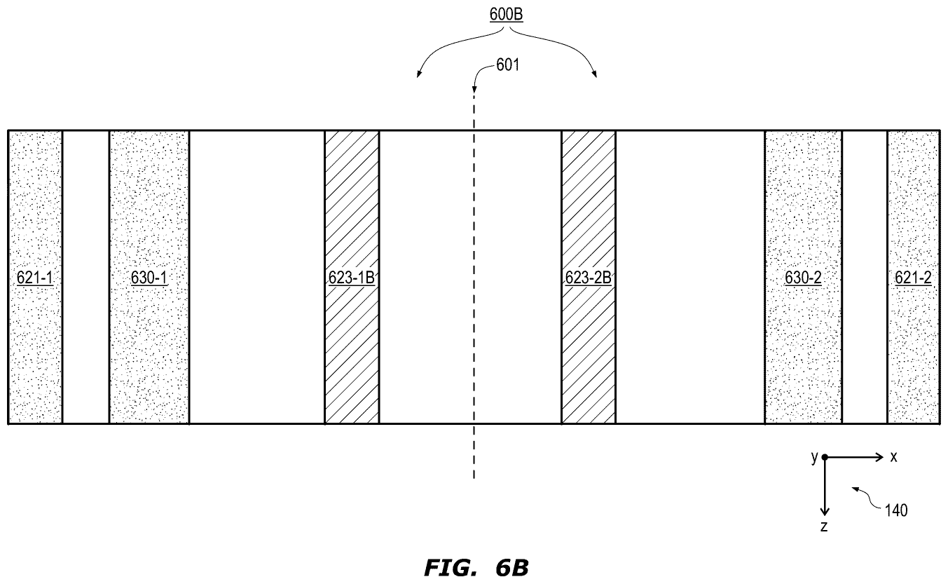

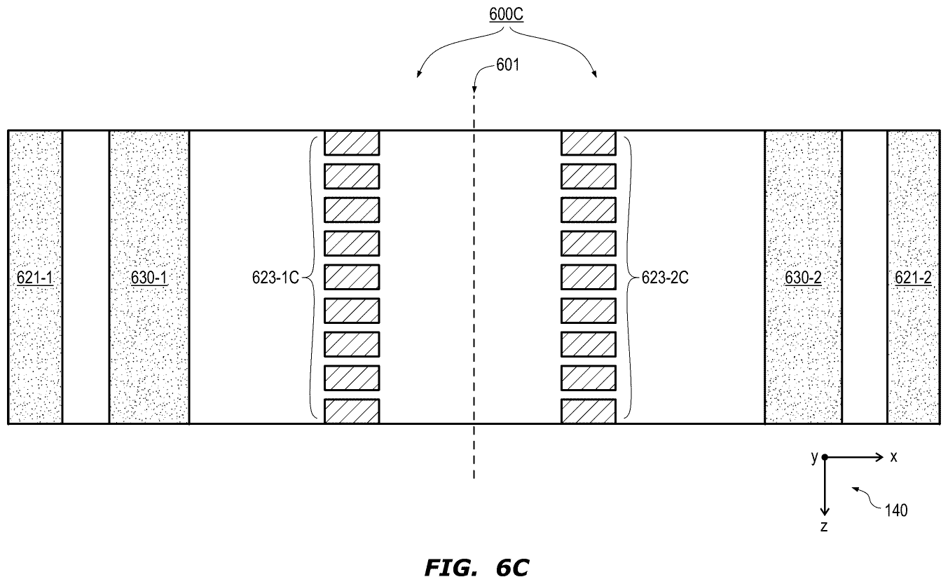

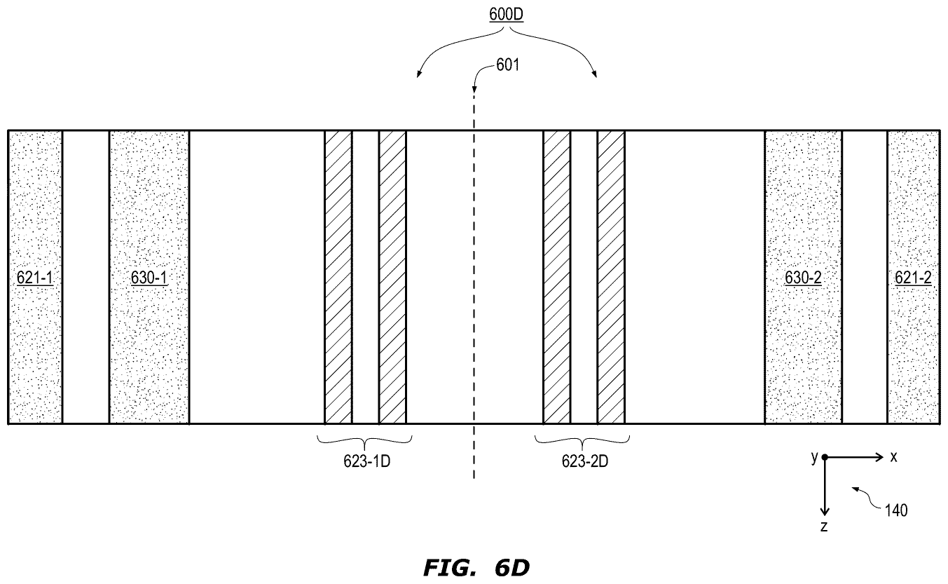

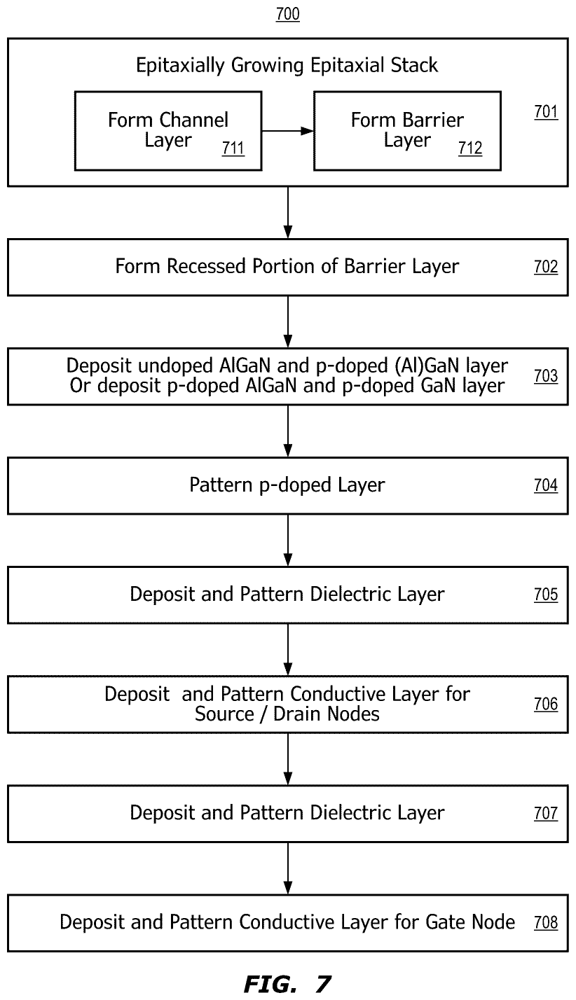

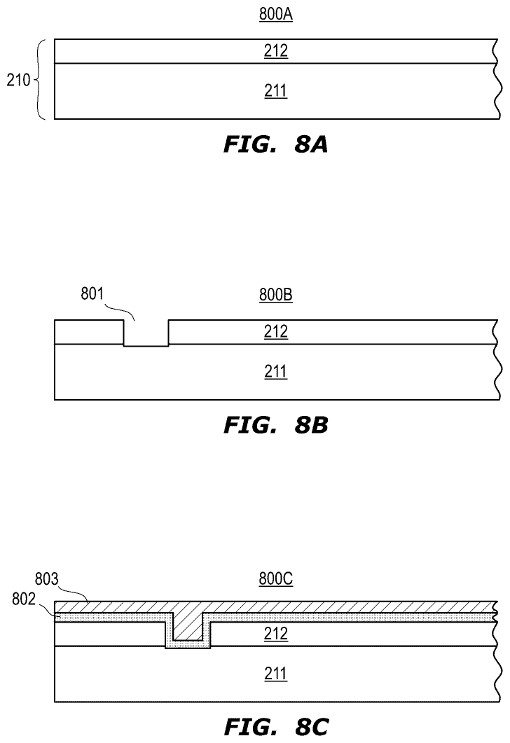

Example embodiments of HEMT structures that use a floating p-doped region to control the electrical field profile of the HEMT structure have been described with respect to FIGS. 2 through 6D. FIG. 7 illustrates a flowchart of a method 700 for fabricating a HEMT structure in accordance with the principles described herein. The method 700 will be described with respect to FIGS. 8A through 8C, FIGS. 9A through 9I, and FIGS. 10A through 10I, which show various stages of fabrication of the HEMT structure 200 of FIG. 2. That said the principles of FIG. 7 may also be used to construct any of the HEMT structures 200, 300, 400, 500, 600A, 600B, 600C and 600D, with the only change being what pattern is use in the patterning stages.

Referring to FIG. 7, the method 700 includes epitaxially growing an epitaxial stack (act 701) that includes forming a channel layer (act 711) formed of a first type III-V semiconductor followed by a barrier layer (act 712) of a second type III-V semiconductor. For example, FIG. 8A shows a structure 800A in which the epitaxial stack 210 has been formed, which includes the channel layer 211 followed by the barrier layer 212. The epitaxial growth of these two layers may be accomplished by a technique including any Physical Vapor Deposition (PVD) or Chemical Vapor Deposition (CVD) techniques. As an example, a channel layer of GaN may be epitaxially grown followed by a barrier layer of AlGaN.

Thereafter, if the p-doped region 223 that is to underly the gate node 230 is to be situated within a recessed region of the barrier layer 212, the recess for the p-doped region is formed (act 702) by appropriate photolithography and etching techniques. Such techniques are known in the art and will not be described in detail herein. The same photolithography and etching techniques may also be used to form a via for the source node to contact the 2DEG. FIG. 8B illustrates the structure 800B, which is the same as the structure 800A of FIG. 8A, except the recess 801 is formed at the appropriate location in the barrier layer 212. Of course, there might be no formation of the recess 801, partial formation of the recess 801 partially or fully through the barrier layer 212, or even partial formation of the recess into the channel layer 211. Although not shown, a recess may also be formed for the floating p-doped region, which is optional but does help to ensure appropriate thinning of the 2DEG underneath the floating p-doped region that will be subsequently formed therein.

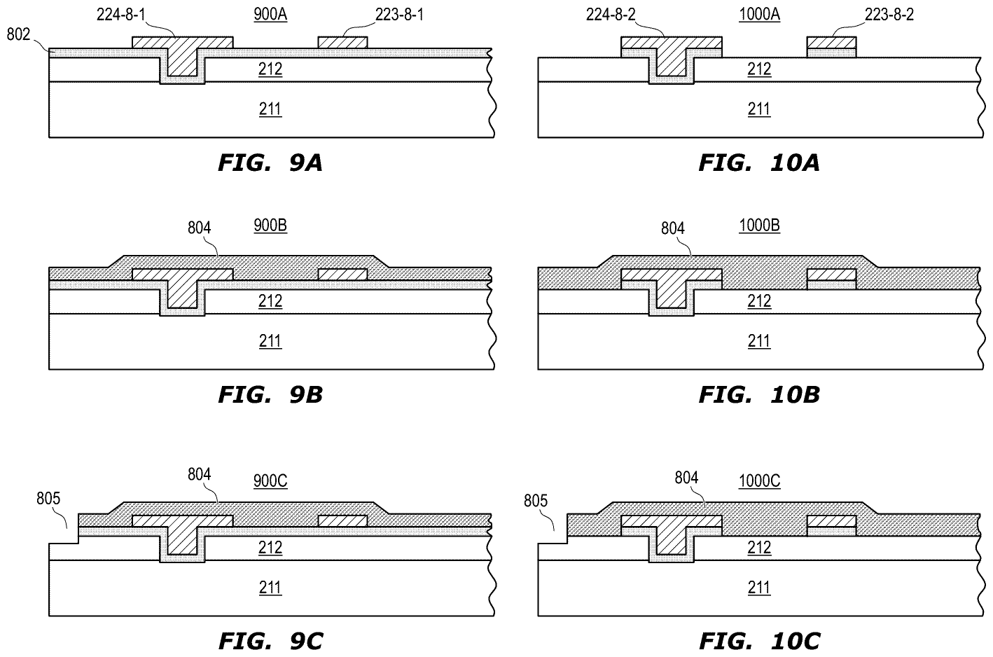

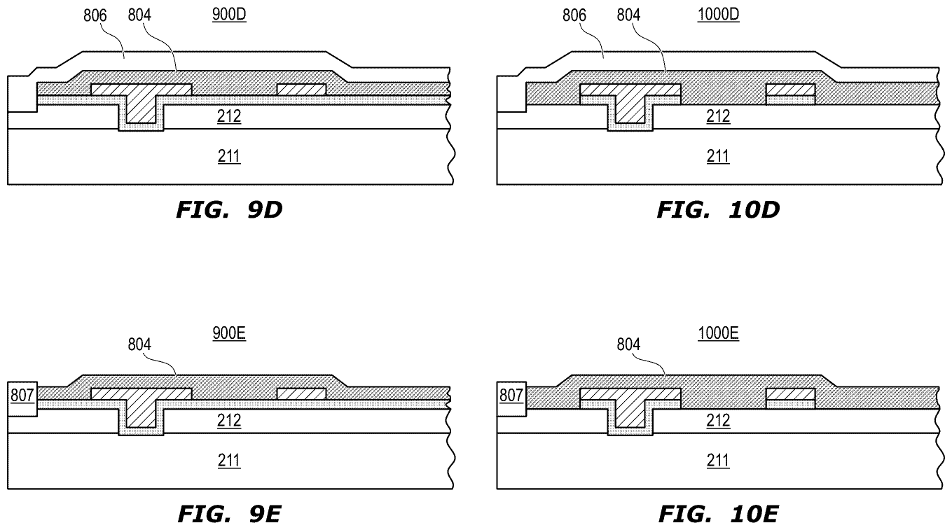

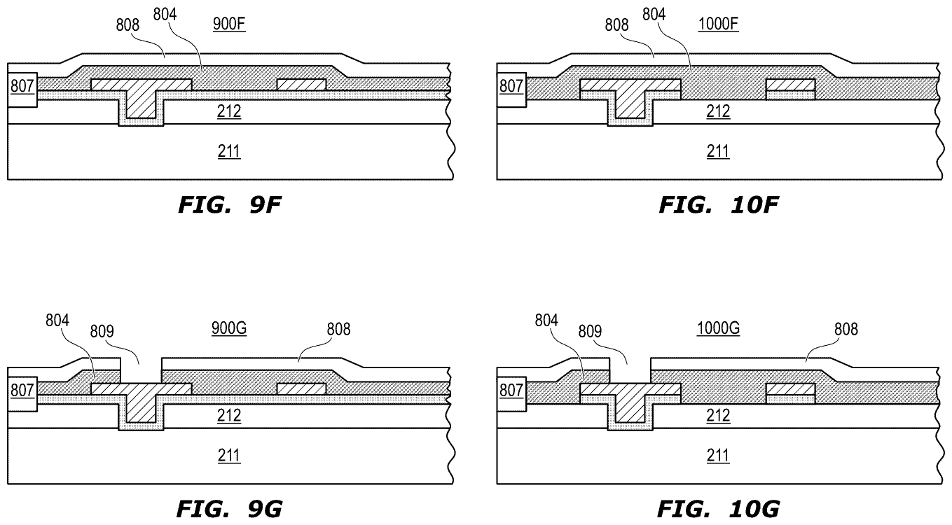

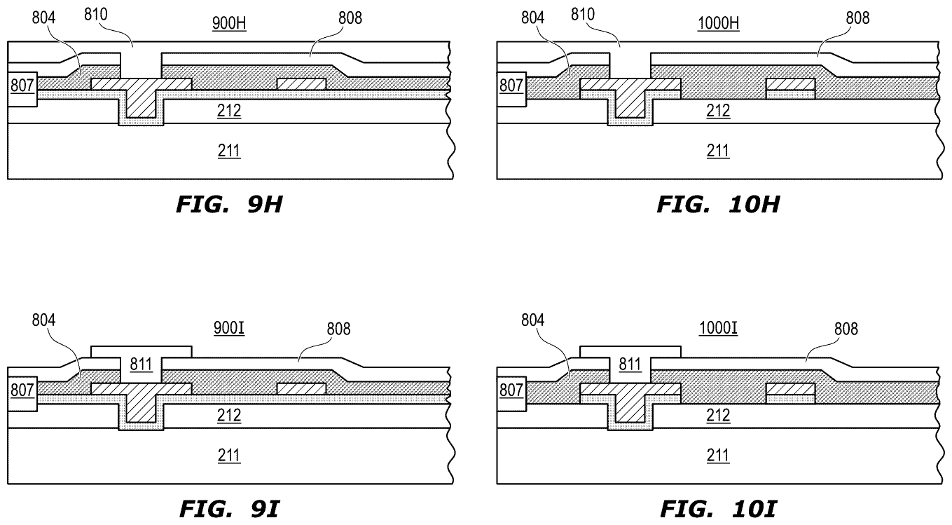

Thereafter, a p-doped layer is deposited (act 703), which may be formed of two layers 802 and 803 as shown in the structure 800C of FIG. 8C. In one embodiment called hereinafter the “First Embodiment”, the first layer 802 might be an undoped AlGaN layer, and the second layer 803 might be a p-doped GaN or AlGaN layer. In an alternative embodiment called hereinafter the “Second Embodiment”, the first layer 802 may be a p-doped AlGaN layer, and the second layer 803 may be a p-doped GaN layer. Subsequent figures will show subsequent structures resulting for processing in both the First Embodiment and the Second Embodiment. For instance, FIGS. 9A through 9I show subsequent structures formed for the First Embodiment. On the other hand, FIGS. 10A through 10I show subsequent structures formed for the Second Embodiment.

Subsequently, the p-doped layer is patterned (act 704) through photolithographic and etching techniques to form the appropriate p-doped regions. FIG. 9A shows a structure 900A of the First Embodiment in which only the second layer 803 of FIG. 8C is selectively etched away leaving a portion of the layer 802 representing the gate node 224-8-1, and a portion of the layer 802 representing the floating p-doped region 223-8-1. On the other hand, FIG. 10A shows a structure 1000A of the Second Embodiment in which both layers 802 and 803 are selectively etched away, leaving a portion of the layer 802 and 803 of FIG. 8C representing the gate node 224-8-2, and a portion of the layers 802 and 803 representing the floating p-doped region 223-8-2. Again, the p-doped region associated with any of the HEMT transistor 300 or the HEMT structures 400, 500 and 600 may likewise be formed in the same manner, with the only difference being the pattern used in the patterning process.

Returning to FIG. 7, a dielectric layer is deposited and patterned (act 705). The dielectric layer is used for passivation. FIG. 9B shows the structure 900B that is similar to the structure 900A of FIG. 9A of the First Embodiment, except that the dielectric layer 804 is deposited. FIG. 10B shows the structure 1000B that is similar to the structure 1000A of FIG. 10A of the Second Embodiment, except that the dielectric layer 804 is deposited. Thus, FIGS. 9B and 10B show the deposition, but not yet the patterning, of the dielectric layer 804.

FIG. 9C shows the structure 900C that is similar to the structure 900B of FIG. 9B of the First Embodiment, except that the dielectric layer 804 has now been patterned to form a recess 805 for the source node (and a similar recess may be formed for the drain node when the structure is to be a single transistor). FIG. 10C shows the structure 1000C that is similar to the structure 1000B of FIG. 10B of the Second Embodiment, except that the dielectric layer 804 has now been patterned to form a recess 805 for the source node (and a similar recess may be formed for the drain node when the structure is to be a single transistor). In either the First Embodiment or the Second Embodiment, there may be either no recess formed for the source node (and drain node), the recess may be formed partially through the barrier layer 212 (as shown in FIGS. 9C and 10C), or the recess may be formed entirely through the barrier layer 212.

Returning to FIG. 7, a conductive layer is deposited and patterned for the source node (and the drain node if the structure forms a single transistor, the drain node) (act 706). FIG. 9D shows the structure 900D that is similar to the structure 900C of FIG. 9C of the First Embodiment, except that the conductive layer 806 is deposited. FIG. 10D shows the structure 1000D that is similar to the structure 1000C of FIG. 10C of the Second Embodiment, except that the conductive layer 806 is deposited. Thus, FIGS. 9D and 10D show the deposition, but not yet the patterning, of the conductive layer 806.

Thereafter, the conductive layer is patterned to form appropriate source nodes and gate nodes, and in the case of FIG. 3, also drain nodes. FIG. 9E shows the structure 900E that is similar to the structure 900D of FIG. 9D of the First Embodiment, except that the conductive layer 806 is now patterned to form the source node 807. FIG. 10E shows the structure 1000E that is similar to the structure 1000D of FIG. 10D of the Second Embodiment, except that the conductive layer is also patterned to form the source node 807.

Returning to FIG. 7, a dielectric layer is deposited and patterned to form a via for the gate node (act 707). FIG. 9F shows the structure 900F that is similar to the structure 900E of FIG. 9E of the First Embodiment, except that the dielectric layer 808 is deposited. FIG. 10F shows the structure 1000F that is similar to the structure 1000E of FIG. 10E of the Second Embodiment, except that the dielectric layer 808 is deposited. Thus, FIGS. 9F and 10F show the deposition, but not yet the patterning, of the dielectric layer 808.

Thereafter, the dielectric layer is patterned to form an appropriate via for the gate node. FIG. 9G shows the structure 900G that is similar to the structure 900F of FIG. 9F of the First Embodiment, except that the dielectric layer 808 is now patterned to form the gate via 809. FIG. 10G shows the structure 1000G that is similar to the structure 100F of FIG. 10F of the Second Embodiment, except that the dielectric layer 808 is now patterned to form the gate via 809.

Returning to FIG. 7, a conductive layer for the gate node is deposited and patterned (act 708). FIG. 9H shows the structure 900H that is similar to the structure 900G of FIG. 9G of the First Embodiment, except that the conductive layer 810 is deposited. FIG. 10H shows the structure 1000H that is similar to the structure 1000G of FIG. 10G of the Second Embodiment, except that the conductive layer 810 is deposited. Thus, FIGS. 9H and 10H show the deposition, but not yet the patterning, of the conductive layer 810.

Thereafter, the conductive layer 810 is patterned to form the gate node. FIG. 91 shows the structure 9001 that is similar to the structure 900H of FIG. 9H of the First Embodiment, except that the conductive layer 810 is now patterned to form the gate 811. FIG. 101 shows the structure 1000I that is similar to the structure 1000H of FIG. 10H of the Second Embodiment, except that the conductive layer 810 is now patterned to form the gate 811.

Accordingly, a HEMT structure and fabrication technique have been described with uses the presence of one or more floating p-doped regions in order effectively manage electrical fields occurring in HEMT structures. This allows the HEMT structure to operate at higher voltages, and promotes the efficient use of electrical power, and the mitigation of electrical waste. This can thereby reduce the need for power generation, thereby having positive impacts on the environment.

### Literal Claim Support Section

Clause 1. A high electron mobility transistor (HEMT) structure comprising: an epitaxial stack comprising: a channel layer composed of a first type III-V semiconductor; and a barrier layer epitaxially grown on the channel layer and composed of a second type III-V semiconductor, the first type III-V semiconductor and the second type III-V semiconductor being such that a heterojunction between the channel layer and the barrier layer forms a two-dimensional electron gas (2DEG) within the channel layer; a gate node positioned over the barrier layer; a source node positioned on a first lateral side of the gate node so as to be in conductive contact with the 2DEG at least when the 2DEG is continuous under the gate node; and a floating p-doped region positioned over the barrier layer and being on a second lateral side of the gate node, the floating p-doped region comprising a third type III-V semiconductor material, the second lateral side being laterally opposite the first lateral side.

Clause 2. The HEMT structure of Clause 1, the third type III-V semiconductor being a same material as the first type III-V semiconductor except for being p-doped.

Clause 3. The HEMT structure of Clause 1, the first type III-V semiconductor being Gallium Nitride (GaN), the second type III-V semiconductor being Aluminum Gallium Nitride (AlGaN).

Clause 4. The HEMT structure of Clause 1, the first type III-V semiconductor being Gallium Arsenide (GaAs), the second type III-V semiconductor being Aluminum Gallium Arsenide (AlGaAs).

Clause 5. The HEMT structure of Clause 1, the first type III-V semiconductor being Indium Gallium Nitride (InGaN), the second type III-V semiconductor being Aluminum Indium Gallium Nitride (AlInGaN).

Clause 6. The HEMT structure of Clause 1, the third type III-V semiconductor being p-doped GaN.

Clause 7. The HEMT structure of Clause 1, the floating p-doped region being a first p-doped region, the HEMT structure further comprising: a second p-doped region positioned vertically between the gate node and the barrier layer, the second p-doped region formed and patterned from a same epitaxial layer in the epitaxial stack as the first p-doped region.

Clause 8. The HEMT structure of Clause 1, the floating p-doped region formed over a recessed portion of the barrier layer.

Clause 9. The HEMT structure of Clause 1, the HEMT structure comprising a HEMT transistor, the source node being a source node of the HEMT transistor, and the gate node being a gate node of the HEMT transistor, the HEMT structure further comprising: a drain node of the HEMT transistor, the drain node positioned on the second lateral side of the floating p-doped region such that when the 2DEG is continuous underneath the gate node, the 2DEG is continuous between the drain node of the HEMT transistor and the source node of the HEMT transistor, rendering the HEMT transistor on.

Clause 10. The HEMT structure of Clause 1, the source node being a first source node, the gate node being a first gate node, the HEMT structure further comprising: a second gate node positioned over the barrier layer on the second lateral side of the floating p-doped region; and a second source node positioned on the second lateral side of the second gate node so as to be in conductive contact with the 2DEG at least when the 2DEG is continuous under the second gate node.

Clause 11. The HEMT structure of Clause 10, the HEMT structure being a bi-directional switch with the first gate node and the second gate node being control nodes for the bi-directional switch and configured to control current flow between the first source node and the second source node through the bi-directional switch.

Clause 12. A high electron mobility (HEMT) structure comprising: an epitaxial stack comprising: a channel layer composed of a first type III-V semiconductor; and a barrier layer epitaxially grown on the channel layer and composed of a second type III-V semiconductor, the first type III-V semiconductor and the second type III-V semiconductor being such that a heterojunction between the channel layer and the barrier layer forms a two-dimensional electron gas (2DEG) within the channel layer; a first gate node positioned over the barrier layer; a first source node positioned on a first lateral side of the first gate node so as to be in conductive contact with the 2DEG at least when the 2DEG is continuous under the gate node; a floating p-doped region positioned over the barrier layer and being on a second lateral side of the gate node, the floating p-doped region comprising a third type III-V semiconductor material, the second lateral side being laterally opposite the first lateral side; a second gate node positioned over the barrier layer on the second lateral side of the floating p-doped region; and a second source node positioned on the second lateral side of the second gate node so as to be in conductive contact with the 2DEG at least when the 2DEG is continuous under the second gate node, the HEMT structure configured to operate as a bi-directional switch with the first gate node and the second gate node being control nodes for the bi-directional switch and configured to control current flow between the first source node and the second source node through the bi-directional switch.

Clause 13. The HEMT structure of Clause 12, the floating p-doped region occupying a lateral mid-point between the first gate node and the second gate node.

Clause 14. The HEMT structure of Clause 12, the floating p-doped region being a first floating p-doped region, the HEMT structure further comprising: a second floating p-doped region positioned over the barrier layer and laterally positioned between the first floating p-doped region and the second gate node.

Clause 15. The HEMT structure of Clause 14, the first floating p-doped region and the second floating p-doped region being laterally symmetrically positioned about a lateral mid-point between the first gate node and the second gate node.

Clause 16. A method for fabricating a HEMT structure, the method comprising: epitaxially growing an epitaxial stack that includes at a channel layer formed of a first type Ill-V semiconductor followed by a barrier layer formed of a second type Ill-V semiconductor; depositing a p-doped layer formed of a third type III-V semiconductor on the epitaxial stack; patterning the p-doped layer to form a first-doped region at a first lateral position over the barrier layer, and a second p-doped region at a second lateral position over the barrier layer, the second lateral position being on a second lateral side of the first lateral position; depositing a conductive layer on the patterned p-doped layer; and patterning the conductive layer to form a gate node over the first p-doped region, and a source node over the barrier layer at a source node lateral position, the source node lateral position being on a first lateral side of the gate node, the second lateral side being laterally opposite the first lateral side.

Clause 17. The method in accordance with Clause 16, the source node being a first source node, the source node lateral position being a first source node lateral position, and the gate node being a first gate node, the patterning of the p-doped layer further forming a third doped region at a third lateral position over the barrier layer, the third lateral position being on the second lateral side of the second lateral position, the patterning of the conductive layer further forming a second gate node over the third p-doped region, and a second source node over the barrier layer at a second source node lateral position, the second source node lateral position being on the second first lateral side of the second gate node, and the second p-doped region occupying a lateral mid-point between the first gate node and the second gate node.

Clause 18. The method in accordance with Clause 16, the source node being a first source node and the source node lateral position being a first source node lateral position, the gate node being a first gate node, the patterning of the p-doped layer further forming a third p-doped region at a third lateral position over the barrier layer, and a fourth p-doped region at a fourth lateral position over the barrier layer, the third lateral position being laterally between the second lateral position and the fourth lateral position, and the patterning of the conductive layer further forming a second gate node over the fourth p-doped region, and a second source node over the barrier layer at a second source node lateral position, the second source node lateral position being on the second first lateral side of the second gate node.

Clause 19. The method in accordance with Clause 18, the patterning of the p-doped layer being such that the second p-doped region and the third p-doped region are laterally symmetric about a lateral mid-point between the first gate node and the second gate node.

Clause 20. The method in accordance with Clause 18, the patterning of the p-doped layer being such that a shape of the second p-doped layer region the shape of the third p-doped region in a plane of epitaxial stack.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A high electron mobility transistor (HEMT) structure comprising:
an epitaxial stack comprising:
a channel layer composed of a first type III-V semiconductor; and
a barrier layer epitaxially grown on the channel layer and composed of a second type III-V semiconductor, the first type III-V semiconductor and the second type III-V semiconductor being such that a heterojunction between the channel layer and the barrier layer forms a two-dimensional electron gas (2DEG) within the channel layer;
a gate node positioned over the barrier layer;
a source node positioned on a first lateral side of the gate node so as to be in conductive contact with the 2DEG at least when the 2DEG is continuous under the gate node; and
a floating p-doped region positioned over the barrier layer and being on a second lateral side of the gate node, the floating p-doped region comprising a third type III-V semiconductor material, the second lateral side being laterally opposite the first lateral side.

2. The HEMT structure of claim 1, the third type III-V semiconductor being a same material as the first type III-V semiconductor except for being p-doped.

3. The HEMT structure of claim 1, the first type III-V semiconductor being Gallium Nitride (GaN), the second type III-V semiconductor being Aluminum Gallium Nitride (AlGaN).

4. The HEMT structure of claim 1, the first type III-V semiconductor being Gallium Arsenide (GaAs), the second type III-V semiconductor being Aluminum Gallium Arsenide (AlGaAs).

5. The HEMT structure of claim 1, the first type III-V semiconductor being Indium Gallium Nitride (InGaN), the second type III-V semiconductor being Aluminum Indium Gallium Nitride (AlInGaN).

6. The HEMT structure of claim 1, the third type III-V semiconductor being p-doped GaN.

7. The HEMT structure of claim 1, the floating p-doped region being a first p-doped region, the HEMT structure further comprising:
a second p-doped region positioned vertically between the gate node and the barrier layer, the second p-doped region formed and patterned from a same epitaxial layer in the epitaxial stack as the first p-doped region.

8. The HEMT structure of claim 1, the floating p-doped region formed over a recessed portion of the barrier layer.

9. The HEMT structure of claim 1, the HEMT structure comprising a HEMT transistor, the source node being a source node of the HEMT transistor, and the gate node being a gate node of the HEMT transistor, the HEMT structure further comprising:
a drain node of the HEMT transistor, the drain node positioned on the second lateral side of the floating p-doped region such that when the 2DEG is continuous underneath the gate node, the 2DEG is continuous between the drain node of the HEMT transistor and the source node of the HEMT transistor, rendering the HEMT transistor on.

10. The HEMT structure of claim 1, the source node being a first source node, the gate node being a first gate node, the HEMT structure further comprising:
a second gate node positioned over the barrier layer on the second lateral side of the floating p-doped region; and
a second source node positioned on the second lateral side of the second gate node so as to be in conductive contact with the 2DEG at least when the 2DEG is continuous under the second gate node.

11. The HEMT structure of claim 10, the HEMT structure being a bi-directional switch with the first gate node and the second gate node being control nodes for the bi-directional switch and configured to control current flow between the first source node and the second source node through the bi-directional switch.

12. A high electron mobility (HEMT) structure comprising:
an epitaxial stack comprising:
a channel layer composed of a first type III-V semiconductor; and
a barrier layer epitaxially grown on the channel layer and composed of a second type III-V semiconductor, the first type III-V semiconductor and the second type III-V semiconductor being such that a heterojunction between the channel layer and the barrier layer forms a two-dimensional electron gas (2DEG) within the channel layer;
a first gate node positioned over the barrier layer;
a first source node positioned on a first lateral side of the first gate node so as to be in conductive contact with the 2DEG at least when the 2DEG is continuous under the gate node;
a floating p-doped region positioned over the barrier layer and being on a second lateral side of the gate node, the floating p-doped region comprising a third type III-V semiconductor material, the second lateral side being laterally opposite the first lateral side;
a second gate node positioned over the barrier layer on the second lateral side of the floating p-doped region; and
a second source node positioned on the second lateral side of the second gate node so as to be in conductive contact with the 2DEG at least when the 2DEG is continuous under the second gate node, the HEMT structure configured to operate as a bi-directional switch with the first gate node and the second gate node being control nodes for the bi-directional switch and configured to control current flow between the first source node and the second source node through the bi-directional switch.

13. The HEMT structure of claim 12, the floating p-doped region occupying a lateral mid-point between the first gate node and the second gate node.

14. The HEMT structure of claim 12, the floating p-doped region being a first floating p-doped region, the HEMT structure further comprising:
a second floating p-doped region positioned over the barrier layer and laterally positioned between the first floating p-doped region and the second gate node.

15. The HEMT structure of claim 14, the first floating p-doped region and the second floating p-doped region being laterally symmetrically positioned about a lateral mid-point between the first gate node and the second gate node.

16. A method for fabricating a HEMT structure, the method comprising:
epitaxially growing an epitaxial stack that includes at a channel layer formed of a first type Ill-V semiconductor followed by a barrier layer formed of a second type Ill-V semiconductor;
depositing a p-doped layer formed of a third type III-V semiconductor on the epitaxial stack;
patterning the p-doped layer to form a first-doped region at a first lateral position over the barrier layer, and a second p-doped region at a second lateral position over the barrier layer, the second lateral position being on a second lateral side of the first lateral position;
depositing a conductive layer on the patterned p-doped layer; and
patterning the conductive layer to form a gate node over the first p-doped region, and a source node over the barrier layer at a source node lateral position, the source node lateral position being on a first lateral side of the gate node, the second lateral side being laterally opposite the first lateral side.

17. The method in accordance with claim 16, the source node being a first source node, the source node lateral position being a first source node lateral position, and the gate node being a first gate node,
the patterning of the p-doped layer further forming a third doped region at a third lateral position over the barrier layer, the third lateral position being on the second lateral side of the second lateral position,
the patterning of the conductive layer further forming a second gate node over the third p-doped region, and a second source node over the barrier layer at a second source node lateral position, the second source node lateral position being on the second first lateral side of the second gate node, and
the second p-doped region occupying a lateral mid-point between the first gate node and the second gate node.

18. The method in accordance with claim 16, the source node being a first source node and the source node lateral position being a first source node lateral position, the gate node being a first gate node,
the patterning of the p-doped layer further forming a third p-doped region at a third lateral position over the barrier layer, and a fourth p-doped region at a fourth lateral position over the barrier layer, the third lateral position being laterally between the second lateral position and the fourth lateral position, and
the patterning of the conductive layer further forming a second gate node over the fourth p-doped region, and a second source node over the barrier layer at a second source node lateral position, the second source node lateral position being on the second first lateral side of the second gate node.

19. The method in accordance with claim 18, the patterning of the p-doped layer being such that the second p-doped region and the third p-doped region are laterally symmetric about a lateral mid-point between the first gate node and the second gate node.

20. The method in accordance with claim 18, the patterning of the p-doped layer being such that a shape of the second p-doped layer region the shape of the third p-doped region in a plane of epitaxial stack.
